(19) United States
(12) Patent Application Publication
(10) Pub. No.: US 2026/0136726 A1
(43) Pub. Date: May 14, 2026

(54) ARRANGEMENTS OF LIGHT-EMITTING DIODE PACKAGES IN LIGHT-EMITTING DEVICES AND RELATED METHODS

(71) Applicant: CreeLED, Inc., Durham, NC (US)

(72) Inventor: Robert David Schmidt, Wake Forest, NC (US)

(21) Appl. No.: 18/947,249

(22) Filed: Nov. 14, 2024

(51) Int. Cl. H01L 33/54; H01L 25/075; H01L 25/13; H01L 33/48; H01L 33/58; H01L 33/62

(52) U.S. Cl. CPC H10H 20/853; H10H 20/8506; H10H 20/857; H10W 90/00; H10H 20/0362; H10H 20/855

(57) ABSTRACT

Light-emitting diode (LED) devices and more particularly arrangements of LED packages in LED devices and related methods are disclosed. LED devices include arrays of LED packages with spacings determined by grid structures. LED packages are partially finished before assembly into LED devices, thereby permitting individual testing and binning of LED packages before device assembly. Partially finished LED packages include primary encapsulants that partially fill recesses thereof to cover associated LED chips. During device assembly, overfill encapsulants are provided that cover the partially finished LED packages and fill portions of each recess above the primary encapsulants. Grid structures may remain as constituent elements in LED devices, or grid structures may be removed before providing overfill encapsulants.

### FIELD OF THE DISCLOSURE

The present disclosure relates to light-emitting diode (LED) devices, and more particularly to arrangements of LED packages in LED devices and related methods.

### BACKGROUND

Light-emitting diodes (LEDs) are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions.

LEDs have been widely adopted in various illumination contexts, for backlighting of liquid crystal display (LCD) systems (e.g., as a substitute for cold cathode fluorescent lamps) and for direct-view LED displays. Applications utilizing LED arrays include vehicular headlamps, roadway illumination, light fixtures, and various indoor, outdoor, and specialty contexts.

Large format multi-color direct-view LED displays (including full color LED video screens) typically include numerous individual LED panels, packages, and/or components providing image resolution determined by the distance between adjacent pixels. For many LED display systems, it is desirable to form LED color groups for each pixel such as primary colors red, green, and blue (RGB) that define vertices of a triangle (or polygon) on a chromaticity diagram. As pixel pitches continue to decrease for higher resolution displays, the density of LED devices used for LED pixels scales higher, thereby adding higher complexity and costs to LED panels for display applications.

The art continues to seek improved LED array devices with small pixel pitches while overcoming limitations associated with conventional devices and production methods.

### SUMMARY

The present disclosure relates to light-emitting diode (LED) devices, and more particularly to arrangements of LED packages in LED devices and related methods. LED devices include arrays of LED packages with spacings determined by grid structures. LED packages are partially finished before assembly into LED devices, thereby permitting individual testing and binning of LED packages before device assembly. Partially finished LED packages include primary encapsulants that partially fill recesses thereof to cover associated LED chips. During device assembly, overfill encapsulants are provided that cover the partially finished LED packages and fill portions of each recess above the primary encapsulants. Grid structures may remain as constituent elements in LED devices, or grid structures may be removed before providing overfill encapsulants.

In one aspect, an LED device comprises: a plurality of LED packages, each LED package comprising a housing and at least one LED chip within a recess of the housing; a grid structure between adjacent LED packages of the plurality of LED packages; and an overfill encapsulant covering the plurality of LED packages and the grid structure. In certain embodiments, the overfill encapsulant partially fills the recess of each LED package of the plurality of LED packages. In certain embodiments, each LED package of the plurality of LED packages comprises a primary encapsulant that partially fills the recess, wherein the primary encapsulant is positioned between the overfill encapsulant and the at least one LED chip. In certain embodiments, the overfill encapsulant covers greater than fifty percent of a sidewall of the recess. In certain embodiments, the grid structure forms a continuous structure around a perimeter of the plurality of LED packages. In certain embodiments, the grid structure comprises sloped sidewalls between adjacent LED packages of the plurality of LED packages. In certain embodiments, the overfill encapsulant laterally extends past peripheral edges of the grid structure.

The LED device may further comprise a device submount on which the plurality of LED packages are mounted, wherein the overfill encapsulant contacts a portion of the device submount. The LED device may further comprise a potting material between the overfill encapsulant and the device submount, wherein the potting material contacts peripheral edges of the housing of each LED package of the plurality of LED packages. The LED device may further comprise a pair of device contact pads on a side of the device submount that is opposite the plurality of LED packages, the pair of device contact pads being electrically coupled to the at least one LED chip in a single LED package of the plurality of LED packages. In certain embodiments, the pair of device contact pads is electrically coupled in series to the at least one LED chip in multiple LED packages of the plurality of LED packages. In certain embodiments, the at least one LED chip comprises a plurality of LED chips within each LED package, wherein the device submount comprises a separate pair of device contact pads for each LED chip of the plurality of LED chips, and each pair of device contact pads is on a side of the device submount that is opposite the plurality of LED packages.

The LED device may further comprise a light collector over the at least one LED chip within the recess of each LED package of the plurality of LED packages. The LED device may further comprise a lens over each LED package of the plurality of LED packages, wherein each lens is positioned at a top surface of the overfill encapsulant. In certain embodiments, the housing is part of a lead frame structure for each LED package of the plurality of LED packages. In certain embodiments, the housing is part of a submount structure for each LED package of the plurality of LED packages.

In another aspect, an LED device comprises: a plurality of LED packages, each LED package comprising a housing, at least one LED chip within a recess of the housing, and a primary encapsulant on the at least one LED chip within the recess of the housing; and an overfill encapsulant covering the plurality of LED packages, the overfill encapsulant on the primary encapsulant within each recess of each LED package of the plurality of LED packages. In certain embodiments, the primary encapsulant partially fills the recess of each LED package, wherein the primary encapsulant is positioned between the overfill encapsulant and the at least one LED chip. In certain embodiments, the overfill encapsulant covers greater than fifty percent of a sidewall of the recess. The LED device may further comprise a device submount on which the plurality of LED packages are mounted, wherein the overfill encapsulant contacts the device submount between adjacent LED packages of the plurality of LED packages. The LED device may further comprise a potting material between the overfill encapsulant and the device submount, wherein the potting material contacts peripheral edges of the housing of each LED package of the plurality of LED packages. The LED device may further comprise a pair of device contact pads on a side of the device submount that is opposite the plurality of LED packages, the pair of device contact pads being electrically coupled to the at least one LED chip in a single LED package of the plurality of LED packages. In certain embodiments, the pair of device contact pads is electrically coupled in series to the at least one LED chip in multiple LED packages of the plurality of LED packages. The LED device may further comprise a light collector over the at least one LED chip within the recess of each LED package of the plurality of LED packages. The LED device may further comprise a lens over each LED package of the plurality of LED packages, wherein each lens is positioned at a top surface of the overfill encapsulant.

In another aspect, a method of forming an LED device comprises: arranging a plurality of LED packages in openings of a grid structure, each LED package comprising a housing, at least one LED chip within a recess of the housing, and a primary encapsulant partially filling the recess; and forming an overfill encapsulant to cover the plurality of LED packages and fill portions of each recess over the primary encapsulant within each LED package of the plurality of LED packages. The method may further comprise selecting the plurality of LED packages from a larger population of LED packages such that the plurality of LED packages are binned within at least one of a wavelength range and an intensity range for the at least one LED chip. In certain embodiments, the plurality of LED packages are selected within the wavelength range and the wavelength range defines a five nanometer range of wavelengths. In certain embodiments, the plurality of LED packages are selected within the intensity range and the intensity range that is within fifteen percent in millicandela of a target intensity. In certain embodiments, forming the overfill encapsulant further comprises covering the grid structure with the overfill encapsulant. The method may further comprise mounting the plurality of LED packages to a device submount with spacings determined by the grid structure. The method may further comprise removing the grid structure before forming the overfill encapsulant.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) device that includes multiple LED packages with a grid structure and an overfill encapsulant according to principles of the present disclosure.

FIG. 1B is a cross-sectional view of the LED device of FIG. 1A taken along the sectional line 1B-1B of FIG. 1A.

FIG. 2 is a cross-sectional view of an LED device similar to the LED device of FIGS. 1A and 1B for embodiments that further include a device submount.

FIG. 3A is a cross-sectional view of the LED device of FIG. 2 at an initial fabrication step where the grid structure is positioned on the device submount.

FIG. 3B is a cross-sectional view of the LED device of FIG. 3A at a subsequent fabrication step after the LED packages are mounted.

FIG. 3C is a cross-sectional view of the LED device of FIG. 3B at a subsequent fabrication step after the overfill encapsulant is formed.

FIG. 4A is a cross-sectional view of another LED device at an initial fabrication step where the grid structure is positioned on the device submount.

FIG. 4B is a cross-sectional view of the LED device of FIG. 4A at a subsequent fabrication step after the LED packages are mounted.

FIG. 4C is a cross-sectional view of the LED device of FIG. 4B at a subsequent fabrication step after removal of the grid structure.

FIG. 4D is a cross-sectional view of the LED device of FIG. 4C at a subsequent fabrication step after the overfill encapsulant is formed.

FIG. 5 is a cross-sectional view of an LED device similar to the LED device of FIGS. 4A to 4D or the LED device of FIG. 2 for embodiments that further include a potting material integrated within the LED device.

FIG. 6 is a cross-sectional view of an LED device similar to the LED device of FIG. 2 for embodiments where the LED packages have a different structure.

FIG. 7 is a cross-sectional view of an LED device similar to the LED device of FIG. 6 for embodiments that further include the potting material.

FIG. 8 is a cross-sectional view of an LED device similar to the LED device of FIG. 6 for embodiments that further include a light collector positioned over the LED chips within each LED package.

FIG. 9 is a cross-sectional view of an LED device similar to the LED device of FIG. 8 for embodiments that further include a lens over each LED package.

FIG. 10A is a top view of an LED device that is similar to the LED device of FIGS. 1A to 1B or the LED device of FIG. 2 with an alternative structure for the LED packages.

FIG. 10B is a bottom view of the LED device of FIG. 10A.

FIG. 11A is a top view of an LED device similar to the device of FIGS. 10A and 10B with a larger number of LED packages.

FIG. 11B is a bottom view of the LED device of FIG. 11A.

FIG. 12A is a top view of an LED device similar to the device of FIGS. 11A and 11B, but with an alternative layout of device contact pads as illustrated in FIG. 12B.

FIG. 12B is a bottom view of the LED device of FIG. 12A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to arrangements of LED packages in LED devices and related methods. LED devices include arrays of LED packages with spacings determined by grid structures. LED packages are partially finished before assembly into LED devices, thereby permitting individual testing and binning of LED packages before device assembly. Partially finished LED packages include primary encapsulants that partially fill recesses thereof to cover associated LED chips. During device assembly, overfill encapsulants are provided that cover the partially finished LED packages and fill portions of each recess above the primary encapsulants. Grid structures may remain as constituent elements in LED devices, or grid structures may be removed before providing overfill encapsulants.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon, aluminum nitride (AlN), and GaN.

The active LED structure may be configured to emit different wavelengths of light depending on the composition of the active LED structure. For example, the active LED structure may emit blue light with a peak wavelength range of approximately 430 nanometers (nm) to 480 nm, or green light with a peak wavelength range of 500 nm to 570 nm, or red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm). For display applications, LED devices of the present disclosure may include multiple chips of different emission wavelengths, such as red, green, and blue to form one or more pixels within an LED display.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED devices and LED packages may include one or more elements, such as lumiphoric materials, encapsulants, light-altering materials, lenses, and electrical contacts, among others that are provided with one or more LED chips. In certain aspects, an LED package may include a support structure or support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. Light-altering materials may be arranged within LED packages to reflect or otherwise redirect light from the one or more LED chips in a desired emission direction or pattern.

In certain embodiments, aspects of the present disclosure relate to LED packages where support structures embody lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

Various performance metrics needed for consideration of LEDs for high-quality video display include resolution, contrast, viewing angle, dynamic range, brightness, frame rate, color gamut, and localized uniformity of wavelength and intensity, among others. Recent advancements in LED packages, improvements in LED driver quality, and cost reductions have greatly improved the resolution, among other requirements. As the resolution has increased, the packing density of LED packages, such as on printed circuit boards (PCBs), has also increased and become more complex.

LED packages with multiple LED chips arranged together to form an LED pixel or multiple LED pixels in a larger LED device have been developed. For example, an LED display may require positioning of many LED packages near one another to form the required pixel array. This may take the form of a panel or tile that forms either the entire LED display or a modular unit that may be arranged with other modules to form the LED display. Challenges exist in achieving consistent uniformity in wavelength and light intensity for each LED pixel in a given LED display. Typically, LED display manufacturers assemble pre-formed LED packages or pre-formed LED chips together to form the panels or tiles. Since the associated LED packages and/or LED chips are separately manufactured, there may be variations in wavelength and light intensity associated with manufacturing deltas that create undesired emission variability in larger LED displays.

In one example, conventional LED packages with multiple pixels are grouped together in an LED display. The singular nature of the LED package provides limited dimensionality and/or flexibility when scaling to larger display sizes. Accordingly, wavelength and/or brightness non-uniformity is compounded in larger LED displays. Other examples include chip-on-board (COB) or glue-on-board (GOB) structures that provide high pixel density for each modular unit, but also suffer uniformity issues with wavelength and/or light intensity consistency across panel (i.e., intra-panel) and between adjacent panels (i.e., inter-panel). This deviation may arise from the construction mechanism of binned LED chips, thereby requiring an entire panel to be binned and treated as one piece. Additionally, variant resistor-capacitor (RC) circuits of each pixel associated with attach and wire differences lead to meaningful differences in the final pixel emission characteristics, regardless of LED chip uniformity. Moreover, high repair issues are associated with chip-failures or wire issues post-encapsulation. In this regard, existing LED panel or LED tile solutions suffer high wavelength and intensity variability across and between panels with difficult binning and associated repair, where pixel-failures can't be identified until the manufacturing process is completed. These solutions also require customized board platforms for installation.

According to aspects of the present disclosure, improved panel solutions are provided by way of binned LED devices that form panels with highly uniform wavelength and intensity profiles across and between panels. Such LED devices advantageously provide a highly modular and pitch-flexible tile or panel system for LED displays or other LED applications. In certain embodiments, the construction is based on pre-binning of partially finished LED packages arranged with a pixel pitch-grid for setting spacing, followed by total tile encapsulation. The binning of partially formed LED packages to tight wavelength and brightness or intensity distributions provides improved uniformity in final devices. Moreover, RC circuit variations associated with electrical connections within each partially formed LED packages are already accounted for during binning. In contrast, conventional COB and GOB devices are formed as one piece, thereby not accounting for such RC circuit variations, regardless of uniformity in binned LED chips. According to aspects of the present disclosure, the encapsulant may complete encapsulation, such as cavity filling, within each LED package, while also overfilling the LED device to form a sealed, smooth, and robust emission surface that may be used as a display tile. Such LED devices may also be tailored to operate as a drop-in to existing single-component screen designs by matching the sub-mount pin layout for ease of manufacture. In various embodiments, such pre-binning includes selecting a plurality of LED packages from a larger group of LED packages such that the plurality of LED packages are binned within at least one of a wavelength range and an intensity range for one or more of the LED chips within each LED package. In one example, the LED packages are binned according to a wavelength range for the one or more LED chips, such as within a 5 nm wavelength range. In another example, the LED packages are binned according to an intensity range for the one or more LED chips, such as within a 15% in millicandela of a target intensity.

As described above, aspects of the present disclosure address the conventional problems of wavelength and/or light intensity consistency by first binning the individual pre-production LED packages for high intra-panel and inter-panel uniformity. The resultant panels also enjoy a flexibility of dimension by simply adjusting the number of LED packages combined per panel to deliver as small as a one-by-two array and as large as is desired, which offers the ability to generate a modular and easily repairable screen module of several small tiles. The final panel may be secured and encapsulated with a continuous layer of encapsulant over-mold that may also serve to seal the sub-mount and LED packages attached thereto. The pixel pitch of the panel may also be highly variable and achieved by tailoring the pitch-grid during positioning.

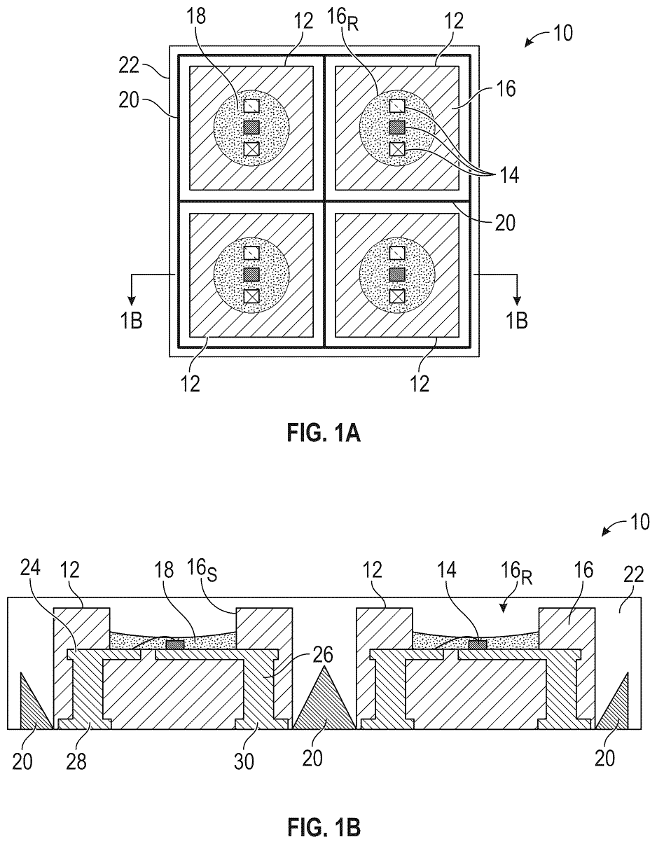

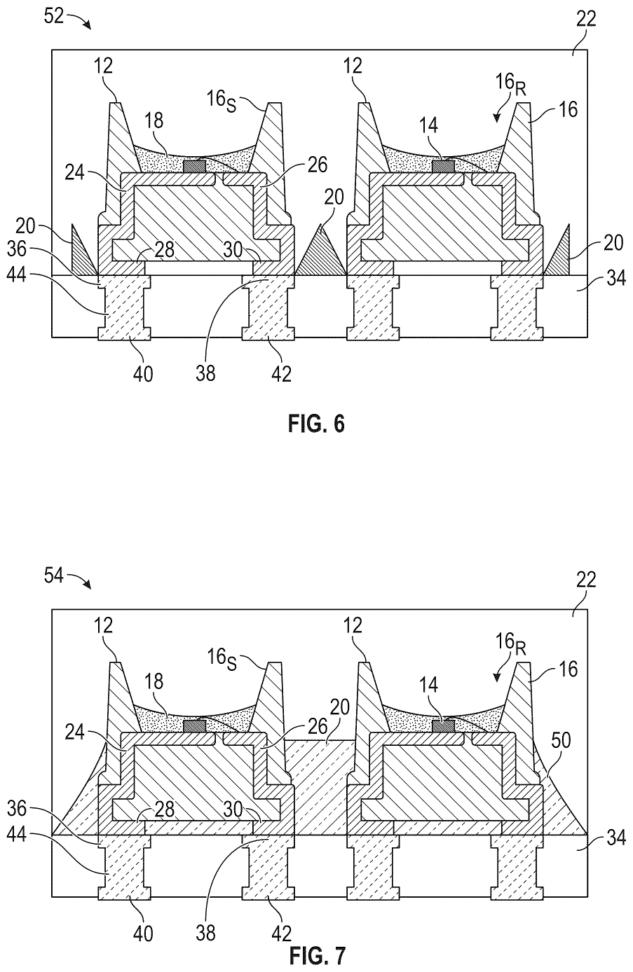

By way of example, the following LED device examples are described in the general context of support structures in partially formed LED packages. The principles described are equally applicable to partially formed LED packages with support structures that embody submount structures and LED packages with support structures that embody lead frame structures. For submount structures, LED packages may include a ceramic submount or a PCB with a housing recess for multiple LED chips being formed therein or by laminate structures that build up from mounting surfaces of LED chips. For lead frame structures, the housing may embody insulating materials that retain portions of a lead frame. Exemplary support structures are illustrated below in the context of through-hole style support structure for the LED packages of FIGS. 1A to 5, and double-bend (e.g., within housing) lead frame style support structures for the LED packages of FIGS. 6 to 9. The principles described are equally applicable to other support structure configurations, such as lead frame structures that laterally extend within housings without complex bending shapes and bend around external portions of the housing.

FIG. 1A is a top view of an LED device 10 that includes multiple LED packages 12 according to principles of the present disclosure. Each LED package 12 may include one or more LED chips 14, for example a red LED chip, a green LED chip, and a blue LED chip for LED pixel applications. Each LED package 12 may include a housing 16 and the LED chips 14 are positioned within a recess 16R of the housing 16. A primary encapsulant 18, such as silicone or the like, is arranged to partially fill the recess 16R. As illustrated, a grid structure 20 is positioned that determines the spacing or pitch between each LED package 12 within the LED device 10. LED packages 12 are arranged in corresponding openings of the grid structure 20. The grid structure 20 may form a continuous structure around a perimeter of the array of LED packages 12 and/or between next-adjacent LED packages 12. As will be described later in greater detail, the grid structure 20 may form a constituent element of the final structure of the LED device 10, or the grid structure 20 may be a sacrificial structure that is later removed. For constituent element embodiments, the grid structure 20 may comprise epoxy, silicone, plastic, ceramic, glass, and/or a same material as the housing 16. In certain embodiments, the grid structure 20 may have a black or dark color for enhanced contrast between LED packages 10. Exemplary materials for the housing 16 may include insulating materials such as PPA, PCT, EMC, FR4, BT, impregnated fiber, plastics, package submounts with recesses, and build up laminates from a submount. For sacrificial embodiments, the grid structure 20 may comprise metal, plastic, ceramic, glass, or any other material that may be readily removed after the pitch between LED packages 12 is set. In certain embodiments, an overfill encapsulant 22 is provided over the LED packages 12 and the grid structure 20.

FIG. 1B is a cross-sectional view of the LED device 10 of FIG. 1A taken along the sectional line 1B-1B of FIG. 1A, thereby illustrating the arrangement of the overfill encapsulant 22 relative to the LED packages 12 and the grid structure 20. As illustrated, the grid structure 20 is between adjacent or neighboring LED packages 12. In certain embodiments, the grid structure 20 forms protrusions that extend upward between the LED packages 12. In still further embodiments, the protrusions of the grid structure 20 include sloped sidewalls to promote self-alignment during placement of each LED package 12.

As illustrated in FIG. 1B, the overfill encapsulant 22 is provided to cover the LED packages 12 and the grid structure 20. In this regard, the overfill encapsulant 22 extends between adjacent LED packages 12 and between portions of the grid structure 20 and nearest LED packages 12. In certain embodiments, the overfill encapsulant 22 laterally extends past peripheral edges of the grid structure 20. The overfill encapsulant 22 effectively secures the LED packages 12 in place relative to the grid structure 20. In certain embodiments, the overfill encapsulant 22 may comprise epoxy, silicone, or any other material that is light-transparent to wavelengths emitted by the LED chips 14. Accordingly, in certain embodiments the overfill encapsulant 22 and the primary encapsulant 18 for each LED package 12 may comprise a same material, just provided at different fabrication steps. As illustrated, the primary encapsulant 18 partially fills the recess 16R to cover the LED chips 14, and also partially covers one or more sidewalls 16s of the recess 16R. The presence of the primary encapsulant 18 within each LED package 12 permits testing and binning of individual LED packages 12 before assembly in the LED device 10. Once assembled, the overfill encapsulant 22 is positioned to extend into and partially fill each recess 16R, thereby providing enhanced anchoring of each LED package 12 relative to one another. Moreover, by extending the overfill encapsulant 22 into the recess 16R, improved resistance to environmental ingress is provided. In certain embodiments, the overfill encapsulant 22 fills the recess 16R to an extent where at least 50% of the one or more sidewalls 16s are covered, or even directly contacted, by the overfill encapsulant 22.

In FIG. 1B, each LED package 12 is illustrated in the context of anode and cathode electrical connections 24, 26 that extend through the housing 16 to reach corresponding package contact pads 28, 30. For lead frame embodiments, the anode and cathode electrical connections 24, 26 and corresponding package contact pads 28, 30 are parts of a lead frame. For submount embodiments, the anode and cathode electrical connections 24, 26 and corresponding package contact pads 28, 30 may be formed by combinations of electrical traces and vias. In certain embodiments, the package contact pads 28, 30 are uncovered by the overfill encapsulant 22 to be accessible for receiving electrical connections for each LED package 12. Accordingly, the LED device 10 may embody a standalone device ready for mounting to a larger structure, such as a fixture or a display.

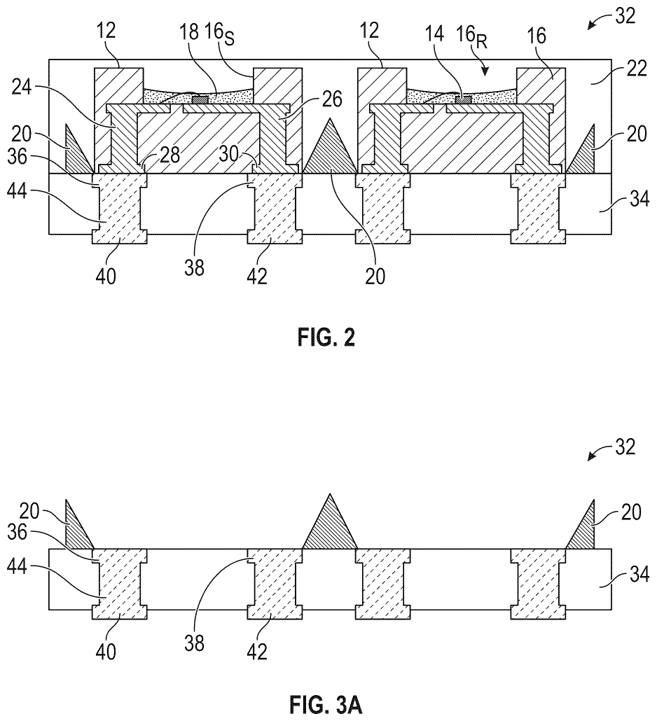

FIG. 2 is a cross-sectional view of an LED device 32 similar to the LED device 10 of FIGS. 1A and 1B for embodiments that further include a device submount 34. The device submount 34 includes corresponding mounting pads 36, 38 for mounting and electrically coupling with the package contact pads 28, 30 of each LED package 12. Device contact pads 40, 42 may be positioned on a bottom side of the device submount 34, opposite from the mounting pads 36, 38, with electrical vias 44 formed therebetween. The presence of the device submount 34 as integrated with the LED device 32 may promote greater flexibility for positioning of the device contact pads 40, 42 for mounting in larger structures, such as fixtures or displays. For example, the device contact pads 40, 42 could be formed with larger sizes and/or different spacing than the package contact pads 28, 30. In certain embodiments, the overfill encapsulant 22 is formed to contact portions of the device submount 34.

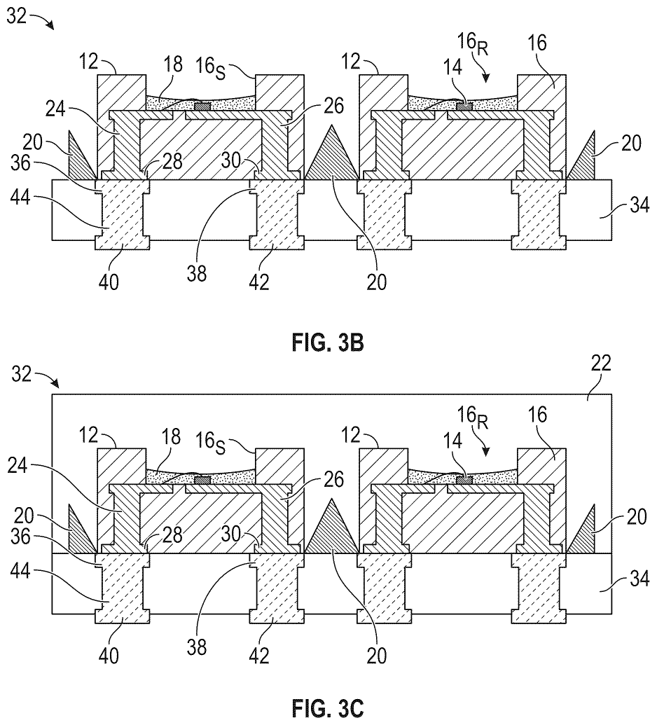

FIGS. 3A to 3C provide a sequence of fabrication steps for forming the LED device 32 of FIG. 2, illustrating the use of the grid structure 20 in setting the pitch between LED packages 12 and the overfill encapsulant 22 for anchoring the LED packages 12 in place. FIG. 3A is a cross-sectional view of the LED device 32 of FIG. 2 at an initial fabrication step. As illustrated, the grid structure 20 is positioned on the device submount 34. The spacing of the grid structure 20 and openings thereof are formed over the corresponding mounting pads 36, 38. FIG. 3B is a cross-sectional view of the LED device 32 of FIG. 3A at a subsequent fabrication step after the LED packages 12 are mounted. Positioning of the LED packages 12 and the pitch therebetween is determined by the layout of the grid structure 20. Finally, as illustrated in FIG. 3C, the overfill encapsulant 22 covers LED packages 12 and the grid structure 20 to anchor them in place. The overfill encapsulant 22 further fills portions of each recess 16R for improved anchoring and ingress resistance.

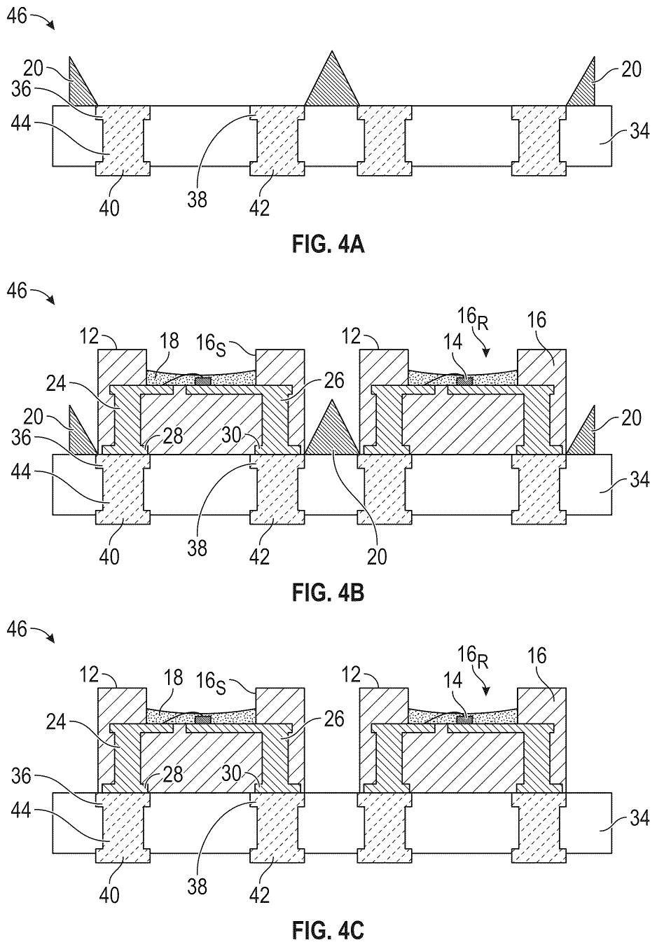

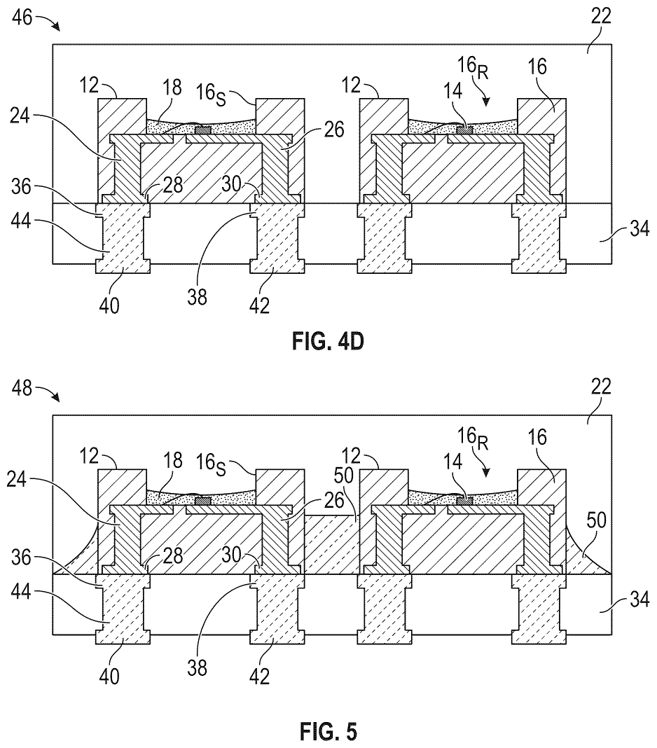

FIGS. 4A to 4C are cross-sectional views of an LED device 46 similar to the LED device 32 of FIG. 3A to 3B for embodiments where the grid structure 20 is sacrificial and not present in the final LED device 46. The fabrication steps illustrated in FIGS. 4A and 4B are similar to those described above for FIGS. 3A and 3B. As illustrated in FIG. 4C, the grid structure 20 of FIG. 4B may be removed after the LED packages 12 are mounted to the device submount 34 and before the overfill encapsulant 22 is formed as illustrated in FIG. 4D. In this regard, the pitch of the LED packages 12 is set by the grid structure 20 before subsequent removal of the grid structure 20. The mounting of the LED packages 12, such as by soldering or direct metal bonding, effectively holds the LED packages 12 in place during removal of the grid structure 20. As illustrated in FIG. 4D, the overfill encapsulant 22 may extend between LED packages 12 a greater distance for further anchoring. In certain embodiments, the overfill encapsulant 22 may even contact the device submount 34 between adjacent LED packages 12.

FIG. 5 is a cross-sectional view of an LED device 48 similar to the LED device 46 of FIGS. 4A to 4D or the LED device 32 of FIG. 2 for embodiments that further include a potting material 50 integrated within the LED device 48. The potting material 50 may be formed after the fabrication step described above with respect to FIG. 4C and before the fabrication step described above with respect to FIG. 4D. The potting material 50 may comprise various materials, such as epoxy or silicone, with a dark or black color and material properties that provide increased protection for moisture ingress while also enhancing contrast between the LED packages 12. The potting material 50 may cover portions of the top surface of the device submount 34 that are uncovered by the LED packages 12, such as around a perimeter of the LED packages 12 and between adjacent LED packages 12. Moreover, the potting material 50 may cover and/or contact peripheral edges of the housing 16 of each LED package 12. The overfill encapsulant 22 may cover the LED packages 12 and partially fill the recesses 16R as described above, while also covering the potting material 50 over the device submount 34. In such an arrangement, the potting material 50 is positioned to effectively cover and provide moisture ingress protection for electrical connections between the LED packages 12 and the device submount 34. In certain embodiments, the grid structure 20 of, for example, FIG. 2 may be present in the LED device 48. In such embodiments, the potting material 50 may effectively cover the grid structure 20.

FIG. 6 is a cross-sectional view of an LED device 52 similar to the LED device 32 of FIG. 2 for embodiments where the LED packages 12 have a different structure. In FIG. 6, the LED packages 12 embody lead frame packages where anode and cathode electrical connections 24, 26 and corresponding package contact pads 28, 30 are respectively formed by different leads of the lead frame. As illustrated, the respective leads that form the anode and cathode electrical connections 24, 26 have multiple bends within the housing 16 to provide increased resistance to moisture ingress. The grid structure 20 and the overfill encapsulant 22 may be formed in a similar manner as described above with respect to any of FIGS. 1A to 5.

FIG. 7 is a cross-sectional view of an LED device 54 similar to the LED device 52 of FIG. 6 for embodiments that further include the potting material 50. As described above with respect to FIG. 5, the potting material 50 may effectively cover the grid structure 20 (e.g., of FIG. 6) in certain embodiments. In other embodiments, the grid structure 20 (e.g., of FIG. 6) may be removed as described above with respect to FIGS. 4A to 4D.

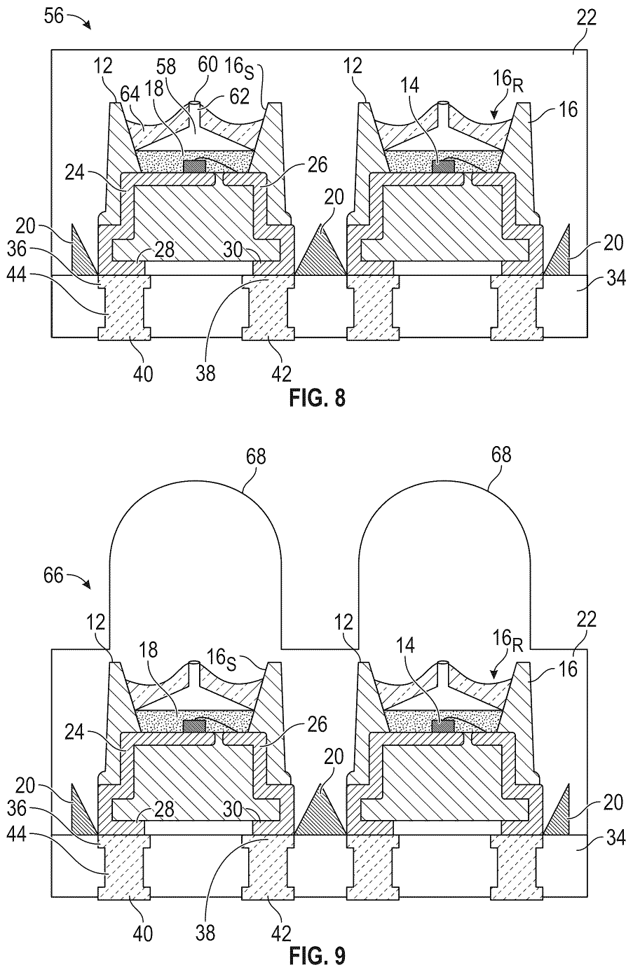

FIG. 8 is a cross-sectional view of an LED device 56 similar to the LED device 52 of FIG. 6 for embodiments that further include a light collector 58 positioned over the LED chips 14 within each LED package 12. The light collector 58 may include an aperture 60 where light emissions from the LED chips 14 escape and a stem portion 62. Light emitted by the LED chips 14 enters the light collector 58 and may reflect one or more times, thereby mixing within the light collector 58 before eventually exiting via the aperture 60. The light mixing within the light collector 58 before exiting via the aperture 60 results in light from each of the LED chips 14 appearing as if the light originated from a single emission point or area (i.e., the aperture 60) instead of from three separate and distinct locations of the LED chips 14 for red-green-blue embodiments. Accordingly, the emission pattern and color over angle shifts of light may be improved. It is to be appreciated that when the present disclosure refers to a single emission point, this is not a point in a mathematical sense, but instead refers to a single emission source (e.g., an LED chip or the output of the plurality of LED chips 14 from the aperture 60). In this sense, a point can be a term for a light source that is smaller than each LED package 12 being described, and the size can depend on the overall system.

In certain embodiments, the light collector 58 may be formed from epoxy, silicone, or some other light-transmissive material. The light collector 58 may be coated with a reflective coating on a top surface thereof except for the aperture 60 at or near the apex, center, or top of the light collector 58. The light collector 58 may comprise a reflective material throughout the light collector 58. For example, the light collector 58 may embody a white material. A secondary encapsulant 64 may be filled and cured on the light collector 58 and in the recess 16R to hold the light collector 58 in place. In certain embodiments, the secondary encapsulant 64 comprises light-transmissive and/or light-transparent materials, such as silicone, epoxy, and polymethyl methacrylate (PMMA), among other encapsulant materials. In further embodiments, since the secondary encapsulant 64 is above the light collector 58, the secondary encapsulant 64 may include a light-reflective material for enhanced brightness or a light-absorbing material for enhanced contrast. As illustrated, the overfill encapsulant 22 may still fill portions of each recess 16R and contact the sidewalls 16s above the light collector 58 and/or the secondary encapsulant 64. In certain embodiments, the potting material 50 as described above with respect to FIG. 7, for example, may be incorporated into the LED device 56 of FIG. 8.

FIG. 9 is a cross-sectional view of an LED device 66 similar to the LED device 56 of FIG. 8 for embodiments that further include a lens 68 over each LED package 12. As illustrated, each lens 68 is positioned at a top surface of the overfill encapsulant 22. In certain embodiments, each lens 68 may be formed as an integrated portion of the overfill encapsulant 22. For example, the material of the overfill encapsulant 22 may be molded over the LED packages 12 and device submount 34 while also being molded to form each lens 68. In other embodiments, each lens 68 may be separately formed on a top surface of the overfill encapsulant 22. In certain embodiments, the potting material 50 as described above with respect to FIG. 7, for example, may be incorporated into the LED device 66 of FIG. 9.

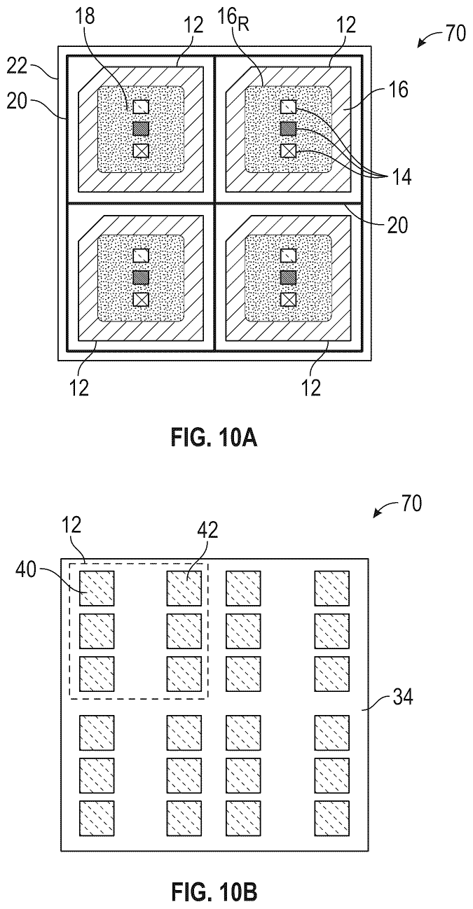

FIG. 10A is a top view of an LED device 70 that is similar to the LED device 10 of FIGS. 1A to 1B or the LED device 32 of FIG. 2 with an alternative structure for the LED packages 12. As illustrated, the housing 16 forms a larger recess 16R in comparison to the structure of FIG. 1. In FIG. 10A, each recess 16R is provided with increased area relative to the housing 16, such as a generally square shape with rounded corners. In this regard, the overfill encapsulant 22 may partially fill the recesses 16R on the primary encapsulants 18 and occupy greater volume within each LED package 12 for increased adhesion.

FIG. 10B is a bottom view of the LED device 70 of FIG. 10A. From this perspective, a bottom surface of the device submount 34 is visible with a layout of the device contact pads 40, 42. For illustrative purposes, a superimposed dashed-line box is provided to show the location of one LED package 12 from FIG. 10A. In the layout of FIG. 10B, three pairs of device contact pads 40, 42 are provided, one pair for each LED chip 14 in each LED package 12. Accordingly, the LED chips 14 within each LED package may be individually addressable. In alternative embodiments where the device submount 34 may not be present, the layout of the device contact pads 40, 42 as illustrated in FIG. 10B may correspond with the layout of the package contact pads 28, 30 of FIG. 1B.

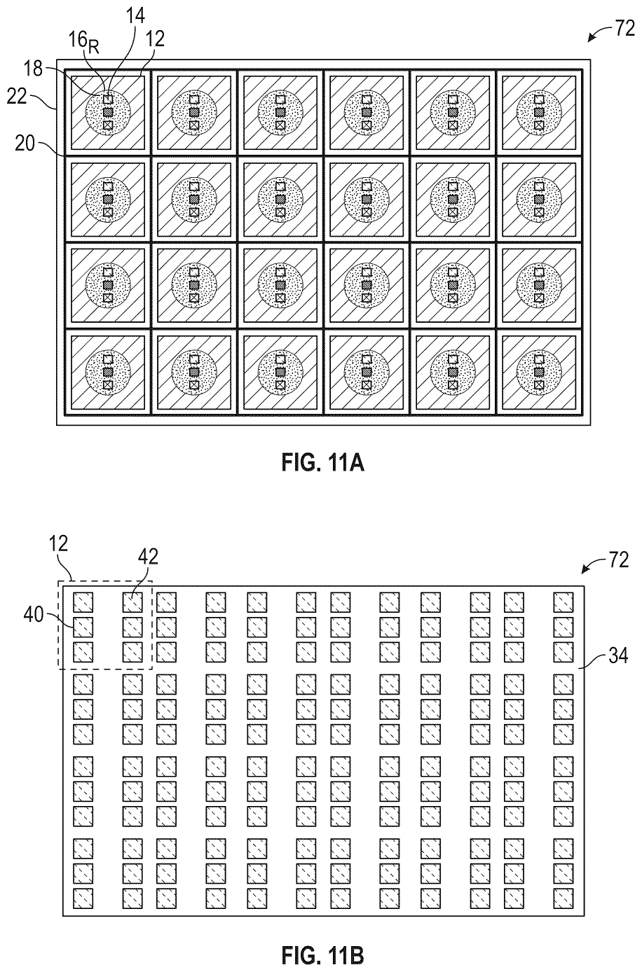

FIG. 11A is a top view of an LED device 72 similar to the device 70 of FIGS. 10A and 10B with a larger number of LED packages 12. FIG. 11B is a bottom view of the LED device 72 of FIG. 11A. In FIG. 11A, the housing 16 and recess 16R are provided with shapes as illustrated in FIG. 1A; however, their shape could also be structured as illustrated in FIG. 10A. According to principles of the present disclosure, relative numbers of LED packages 12 may be scaled up or down to target specific applications. By way of example, the LED device 72 of FIG. 11A includes twenty-four LED packages 12. According to the fabrication sequences described above with respect to FIGS. 3A to 3C or FIGS. 4A to 4D, the number of LED packages 12 per device is easily scalable. As such, larger numbers of LED packages 12 may be pre-tested and binned before being combined in a larger device that may form an entire display or a larger modular block of a display. In a similar manner as described with respect to FIG. 10B, each LED package 12 for the LED device 72 of FIGS. 11A and 11B may have corresponding pairs of the device contact pads 40, 42 for each LED chip 14. In alternative embodiments where the device submount 34 may not be present, the layout of the device contact pads 40, 42 as illustrated in FIG. 11B may correspond with the layout of the package contact pads 28, 30 of FIG. 1B.

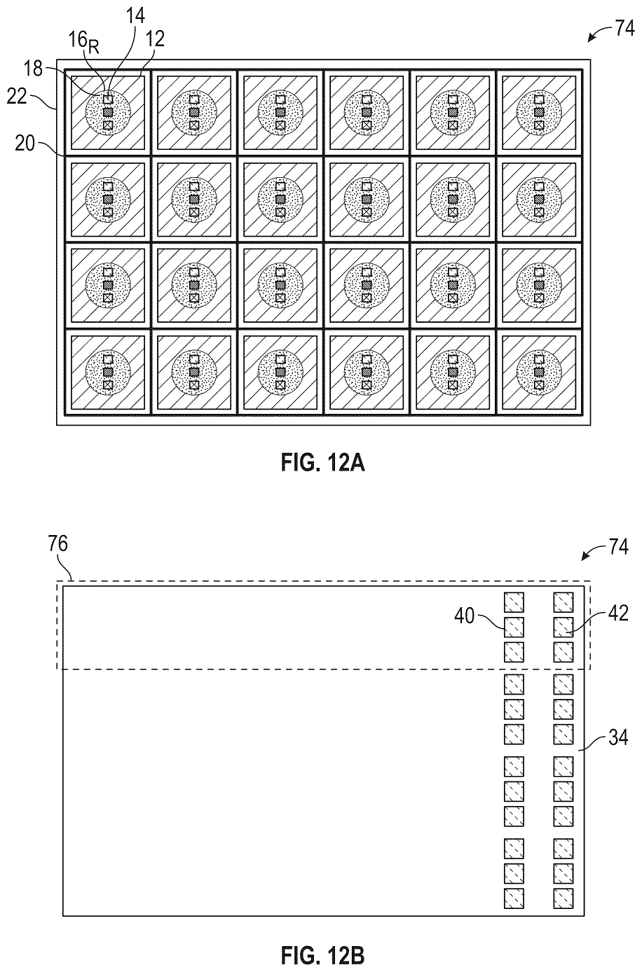

FIG. 12A is a top view of an LED device 74 similar to the device 72 of FIGS. 11A and 11B, but with an alternative layout of device contact pads 40, 42 as illustrated in FIG. 12B. FIG. 12B is a bottom view of the LED device 74 of FIG. 12A. From the top view of FIG. 12A, the LED device 74 may have a same structure as described above with respect to FIG. 11A. However, the device submount 34 may have an alternative layout with fewer pairs of device contact pads 40, 42 than LED packages 12. As described above, the device submount 34 may embody a printed circuit board, and printed circuit boards with multiple-layer structures may allow flexibility in electrical configurations for the LED device 74. Accordingly, layouts of internal vias and/or electrical traces may readily be structured within the device submount 34 to allow for groupings of device contact pads 40, 42 that control multiple LED packages 12. By way of example, a superimposed dashed-line box 76 in FIG. 12B illustrates locations of LED packages 12 from FIG. 12A that may be controlled with the same grouping of device contact pads 40, 42. In this example, the top row of LED packages 12 of FIG. 12A may be coupled to the same three pairs of device contact pads 40, 42 of FIG. 12B. In certain embodiments, individual LED chips 14 of similar emission wavelengths may be serially connected across multiple LED packages 12, such as serial connections for each red LED chip in each LED package 12, with similar serial arrangements for each blue LED chip and each green LED chip.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein. For example, any of the LED devices described above with respect to FIGS. 1A to 12B may include the grid structure 20 in final device form (e.g., FIG. 1B and FIG. 2) or the grid structure 20 may be removed in final device form (e.g., FIG. 4D). Additionally, the potting material 50 of FIGS. 5 and 7 may be implemented in combination with any of the embodiments of FIGS. 1A to 12B. Moreover, the light collector 58, the secondary encapsulant 64, and/or the lens 68 arrangements of FIGS. 8 and 9 may be implemented in combination with any of the embodiments of FIGS. 1A to 7 and 10A to 12B.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) device comprising:
a plurality of LED packages, each LED package comprising a housing and at least one LED chip within a recess of the housing;
a grid structure between adjacent LED packages of the plurality of LED packages; and
an overfill encapsulant covering the plurality of LED packages and the grid structure.

2. The LED device of claim 1, wherein the overfill encapsulant partially fills the recess of each LED package of the plurality of LED packages.

3. The LED device of claim 2, wherein each LED package of the plurality of LED packages comprises a primary encapsulant that partially fills the recess, wherein the primary encapsulant is positioned between the overfill encapsulant and the at least one LED chip.

4. The LED device of claim 3, wherein the overfill encapsulant covers greater than fifty percent of a sidewall of the recess.

5. The LED device of claim 1, wherein the grid structure forms a continuous structure around a perimeter of the plurality of LED packages.

6. The LED device of claim 5, wherein the grid structure comprises sloped sidewalls between adjacent LED packages of the plurality of LED packages.

7. The LED device of claim 1, wherein the overfill encapsulant laterally extends past peripheral edges of the grid structure.

8. The LED device of claim 1, further comprising a device submount on which the plurality of LED packages are mounted, wherein the overfill encapsulant contacts a portion of the device submount.

9. The LED device of claim 8, further comprising a potting material between the overfill encapsulant and the device submount, wherein the potting material contacts peripheral edges of the housing of each LED package of the plurality of LED packages.

10. The LED device of claim 8, further comprising a pair of device contact pads on a side of the device submount that is opposite the plurality of LED packages, the pair of device contact pads being electrically coupled to the at least one LED chip in a single LED package of the plurality of LED packages.

11. The LED device of claim 10, wherein the pair of device contact pads is electrically coupled in series to the at least one LED chip in multiple LED packages of the plurality of LED packages.

12. The LED device of claim 8, wherein the at least one LED chip comprises a plurality of LED chips within each LED package, wherein the device submount comprises a separate pair of device contact pads for each LED chip of the plurality of LED chips, and each pair of device contact pads is on a side of the device submount that is opposite the plurality of LED packages.

13. The LED device of claim 1, further comprising a light collector over the at least one LED chip within the recess of each LED package of the plurality of LED packages.

14. The LED device of claim 1, further comprising a lens over each LED package of the plurality of LED packages, wherein each lens is positioned at a top surface of the overfill encapsulant.

15. The LED device of claim 1, wherein the housing is part of a lead frame structure for each LED package of the plurality of LED packages.

16. The LED device of claim 1, wherein the housing is part of a submount structure for each LED package of the plurality of LED packages.

17. A light-emitting diode (LED) device comprising:
a plurality of LED packages, each LED package comprising a housing, at least one LED chip within a recess of the housing, and a primary encapsulant on the at least one LED chip within the recess of the housing; and
an overfill encapsulant covering the plurality of LED packages, the overfill encapsulant on the primary encapsulant within each recess of each LED package of the plurality of LED packages.

18. The LED device of claim 17, wherein the primary encapsulant partially fills the recess of each LED package, wherein the primary encapsulant is positioned between the overfill encapsulant and the at least one LED chip.

19. The LED device of claim 18, wherein the overfill encapsulant covers greater than fifty percent of a sidewall of the recess.

20. The LED device of claim 17, further comprising a device submount on which the plurality of LED packages are mounted, wherein the overfill encapsulant contacts the device submount between adjacent LED packages of the plurality of LED packages.

21. The LED device of claim 20, further comprising a potting material between the overfill encapsulant and the device submount, wherein the potting material contacts peripheral edges of the housing of each LED package of the plurality of LED packages.

22. The LED device of claim 20, further comprising a pair of device contact pads on a side of the device submount that is opposite the plurality of LED packages, the pair of device contact pads being electrically coupled to the at least one LED chip in a single LED package of the plurality of LED packages.

23. The LED device of claim 22, wherein the pair of device contact pads is electrically coupled in series to the at least one LED chip in multiple LED packages of the plurality of LED packages.

24. The LED device of claim 17, further comprising a light collector over the at least one LED chip within the recess of each LED package of the plurality of LED packages.

25. The LED device of claim 17, further comprising a lens over each LED package of the plurality of LED packages, wherein each lens is positioned at a top surface of the overfill encapsulant.

26. A method of forming a light-emitting diode (LED) device, the method comprising:
arranging a plurality of LED packages in openings of a grid structure, each LED package comprising a housing, at least one LED chip within a recess of the housing, and a primary encapsulant partially filling the recess; and
forming an overfill encapsulant to cover the plurality of LED packages and fill portions of each recess over the primary encapsulant within each LED package of the plurality of LED packages.

27. The method of claim 26, further comprising selecting the plurality of LED packages from a larger population of LED packages such that the plurality of LED packages are binned within at least one of a wavelength range and an intensity range for the at least one LED chip.

28. The method of claim 27, wherein the plurality of LED packages are selected within the wavelength range and the wavelength range defines a five nanometer range of wavelengths.

29. The method of claim 27, wherein the plurality of LED packages are selected within the intensity range and the intensity range that is within fifteen percent in millicandela of a target intensity.

30. The method of claim 26, wherein forming the overfill encapsulant further comprises covering the grid structure with the overfill encapsulant.

31. The method of claim 26, further comprising mounting the plurality of LED packages to a device submount with spacings determined by the grid structure.

32. The method of claim 31, further comprising removing the grid structure before forming the overfill encapsulant.
